(19) United States
(12) Patent Application Publication
(10) Pub. No.: US 2025/0212666 A1
(43) Pub. Date: Jun. 26, 2025

(54) DISPLAY DEVICE

(71) Applicant: LG Display Co., Ltd., Seoul (KR)

(72) Inventors: Yuri PARK, Paju-si (KR); Moonsung KIL, Paju-si (KR); EunYoung PARK, Paju-si (KR); Sora PARK, Paju-si (KR)

(21) Appl. No.: 18/929,296

(22) Filed: Oct. 28, 2024

(30) Foreign Application Priority Data
Dec. 26, 2023 (KR) 10-2023-0191373

(51) Int. Cl. H10K 59/80; H10K 59/122; H10K 59/126; H10K 59/13; H10K 59/35; H10K 59/88

(52) U.S. Cl. CPC H10K 59/8792; H10K 59/122; H10K 59/126; H10K 59/13; H10K 59/352; H10K 59/353; H10K 59/88

(57) ABSTRACT

The present disclosure provides to a display device. The display device includes either a coating layer or a dummy emission layer covering at least a portion of a bank layer, and is capable of absorbing or blocking light emitted downwards from an emission layer due to lateral leakage current.

### CROSS-REFERENCE TO RELATED APPLICATION

This application claims the priority benefit of Republic of Korea Patent Application No. 10-2023-0191373, filed on Dec. 26, 2023 in the Korean Intellectual Property Office, which is incorporated herein by reference for all purposes as if fully set forth herein.

### BACKGROUND

### Technical Field

The present disclosure relates to electronic devices with displays, and more specifically, to display devices.

### Description of the Related Art

As display technology has been developed to provide increased functions, display devices can provide an image capturing function, a sensing function, and the like, as well as an image display function.

To provide these functions, display devices may need to include an optical electronic device, such as a light receiving device, a camera, a sensor for detecting an image, and the like.

In order to receive light passing through the front surface of display devices, it may be desirable for such an optical electronic device to be located in an area of the display devices where incident light coming from the front surface can be increasingly received and detected.

To achieve the foregoing, in display devices, an optical electronic device has been designed to be located in a front portion of the display devices to allow a camera, a sensor, and/or the like as the optical electronic device to be increasingly exposed to incident light.

In order to install an optical electronic device in display devices in this manner, a bezel area of the display devices may be increased, or a notch or a hole may be needed to be formed in a display area of an associated display panel.

### BRIEF SUMMARY

When optical electronic devices (e.g., camera modules, sensors, etc.) are incorporated into display devices, it may be beneficial for the display devices to have higher transmittance. This would allow the optical electronic devices that receive or detect incident light to perform their intended functions effectively when attached to the display devices. The inventors of the present disclosure have provided various embodiments of a display device that prevents light emitted downwards by an emission layer due to lateral leakage current.

One or more aspects of the present disclosure may provide a display device capable of absorbing light emitted downwards by an emission layer due to lateral leakage current.

One or more aspects of the present disclosure may provide a display device capable of shielding light emitted downwards by an emission layer due to lateral leakage current.

According to one or more example embodiments of the present disclosure, a display device can be provided that includes a substrate including a display area in which a plurality of subpixels are disposed, an electrode layer located over the substrate, a bank layer covering a portion of the electrode layer, a coating layer covering at least a portion of the bank layer and including a light absorbing material, and an emission layer located on the electrode layer, the bank layer and the coating layer.

According to one or more example embodiments of the present disclosure, a display device can be provided that includes a substrate including a display area in which a plurality of subpixels are disposed, an electrode layer located over the substrate, a bank layer covering a portion of the electrode layer, a dummy emission layer covering at least a portion of the bank layer and including a light emitting material, a hole transport layer located on the electrode layer and the bank layer and covering the dummy emission layer, and a main emission layer located on the hole transport layer.

According to one or more aspects of the present disclosure, a display device may be provided that is capable of absorbing or shielding light emitted downwards by an emission layer due to lateral leakage current.

According to one or more aspects of the present disclosure, a display device may be provided that is capable of being driven with low power based on the improved performance of one or more sensors by absorbing or shielding light emitted downwards by an emission layer due to lateral leakage current.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 is a plan view of an example display device according to aspects of the present disclosure;

FIG. 2 illustrates an example system configuration of the display device according to aspects of the present disclosure;

FIG. 3 illustrates an example equivalent circuit of a subpixel in a display panel according to aspects of the present disclosure;

FIG. 4 illustrates arrangements of subpixels in example three areas included in a display area of the display device according to aspects of the present disclosure;

FIGS. 5A and 5B are example enlarged plan views of a second optical area OA2 of FIG. 4 according to aspects of the present disclosure; and

FIGS. 6A and 6B are example cross-sectional views taken along line A-A′ of FIG. 5B according to aspects of the present disclosure.

### DETAILED DESCRIPTION

Reference will now be made in detail to example embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals designate like elements throughout, unless otherwise specified.

Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings.

The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. In the following description, where the detailed description of the relevant known function or configuration may unnecessarily obscure aspects of the present disclosure, a detailed description of such known function or configuration may be omitted.

Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, etc., are mentioned, it should be considered that numerical values for an elements or features, or corresponding information (e.g., level, range, etc.) include a tolerance or error range (e.g., 5%) that may be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various example embodiments of the present disclosure will be described in detail.

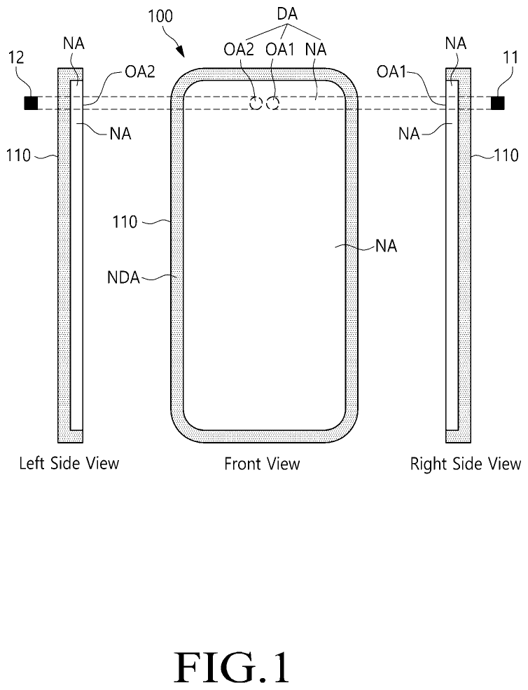

FIG. 1 is a plan view of an example display device 100 according to aspects of the present disclosure.

Referring to FIG. 1, in one or more example embodiments, the display device 100 may include a display panel 110 for displaying an image, and one or more optical electronic devices (11 and/or 12). Herein, an optical electronic device may be referred to as a light detector, a light receiver, or a light sensing device. An optical electronic device may include one or more of a camera, a camera lens, a sensor, a sensor for detecting images, or the like.

The display panel 110 may include a display area DA configured to allow one or more images to be displayed and a non-display area NDA in which an image is not displayed.

A plurality of subpixels may be disposed in the display area DA, and several types of signal lines for driving the plurality of subpixels may be disposed therein.

The non-display area NDA may refer to an area outside of the display area DA.

Several types of signal lines may be disposed in the non-display area NDA, and several types of driving circuits may be connected thereto.

At least a portion of the non-display area NDA may be bent to be invisible from the front surface of the display device 100 or may be covered by a case or housing (not shown) of the display device 100.

The non-display area NDA may be also referred to as a bezel or a bezel area.

Referring to FIG. 1, in one or more aspects, the one or more optical electronic devices (11 and/or 12) included in the display device 100 may be located under, or in a lower portion of, the display panel 110 (an opposite side to the viewing surface thereof).

Light can enter the front surface (the viewing surface) of the display panel 110, pass through the display panel 110, reach one or more optical electronic devices (11 and/or 12) located under, or in the lower portion of, the display panel 110 (the opposite side of the viewing surface).

The one or more optical electronic devices (11 and/or 12) may be devices capable of receiving or detecting light passing through the display panel 110 and perform a predefined function based on the received light.

For example, the one or more optical electronic devices (11 and/or 12) may include one or more of the following: an image capture device such as a camera (an image sensor), and/or the like; or a sensor such as a proximity sensor, an illuminance sensor, and/or the like.

For example, the illuminance sensor may be an ambient light sensor, but example embodiments of the present disclosure are not limited thereto.

In a state where the display device 100 is turned off, the display device 100 can detect ambient light using the illuminance sensor, and adjust the luminance of an image on a screen displayed through the display panel 110 based on the brightness of the ambient light.

Referring to FIG. 1, in one or more aspects, the display area DA defined in the display panel 110 may include a normal area NA and one or more optical areas (OA1 and/or OA2). Herein, the term “normal area” NA may be an area that while being present in the display area DA, does not overlap with one or more optical electronic devices (11 and/or 12). The normal area NA may also be referred to as a non-optical area.

Referring to FIG. 1, the one or more optical areas (OA1 and/or OA2) may be one or more areas respectively overlapping the one or more optical electronic devices (11 and/or 12).

According to the example of FIG. 1, the display area DA may include a normal area NA, a first optical area OA1, and a second optical area OA2.

In the example of FIG. 1, a portion of the normal area NA may be present between the first optical area OA1 and the second optical area OA2.

Although FIG. 1 illustrates a structure in which each of the first and second optical area (OA1 and OA2) has a circular shape, respective shapes of the first and second optical area (OA1 and OA2) according to example embodiments of the present disclosure are not limited thereto.

In one or more aspects, the first optical area OA1 may have various shapes, such as a circle, an ellipse, a quadrangle, a hexagon, an octagon or the like.

In one or more aspects, the second optical area OA2 may have various shapes, such as a circle, an ellipse, a quadrangle, a hexagon, an octagon or the like.

The first optical area OA1 and the second optical area OA2 may have the same or substantially or nearly the same shape, or different shapes.

Hereinafter, for convenience of description, discussions are provided based on examples where each of the first optical area OA1 and the second optical area OA2 has a circular shape. It should be, however, understood that the scope of the present disclosure includes examples where at least one of the first optical area OA1 and the second optical area OA2 has a shape other than the circular shape.

In this example, at least a portion of the first optical area OA1 may overlap with the first optical electronic device 11, and at least a portion of the second optical area OA2 may overlap with the second optical electronic device 12.

In one or more aspects, the one or more optical areas (OA1 and/or OA2) included in the display panel 110 or the display device 100 are needed to be configured with both an image display structure and a light transmissive structure.

For example, since the one or more optical areas (OA1 and/or OA2) are respective portions of the display area DA, therefore, it is desirable that subpixels for displaying images are disposed in the one or more optical areas (OA1 and/or OA2).

Further, to enable light entering the display panel 110 or the display device 100 to reach the one or more optical electronic devices (11 and/or 12), it is also desirable that each of the one or more optical areas (OA1 and/or OA2) is configured with a light transmissive structure.

It should be noted that even though the one or more optical electronic devices (11 and/or 12) are devices that need to receive light, the one or more optical electronic devices (11 and/or 12) may be located on the back of the display panel 110 (e.g., on an opposite side of the viewing surface thereof). Therefore, the one or more optical electronic devices (11 and/or 12) can receive light that has passed through the display panel 110.

For example, the one or more optical electronic devices (11 and/or 12) may not be exposed in the front surface (viewing surface) of the display panel 110 or the display device 100.

Accordingly, when a user views the front surface of the display device 100, the one or more optical electronic devices (11 and/or 12) are located so that they cannot be visible to the user.

The first optical electronic device 11 may be, for example, a camera, and the second optical electronic device 12 may be, for example, a sensor. The sensor may be a proximity sensor, an illuminance sensor, an infrared sensor, and/or the like.

In one or more aspects, the camera may be a camera lens, an image sensor, or a unit including at least one of the camera lens and the image sensor, and the sensor may be an infrared sensor capable of detecting infrared light.

In one or more aspects, the first optical electronic device 11 may be a sensor, and the second optical electronic device 12 may be a camera.

Hereinafter, for convenience of description, discussions are provided based on examples where the first optical electronic device 11 is a camera, and the second optical electronic device 12 is a sensor. It should be, however, understood that the scope of the present disclosure includes examples where the first optical electronic device 11 is the sensor, and the second optical electronic device 12 is the camera.

The camera may be, for example, a camera lens, an image sensor, or a unit including at least one of the camera lens and the image sensor.

In an example where the first optical electronic device 11 is a camera, this camera may be located on the back of (e.g., under, or in a lower portion of) the display panel 110, and be a front camera for capturing objects or images in a front direction of the display panel 110.

Accordingly, the user can capture an image or object through the camera that is invisible on the viewing surface while looking at the viewing surface of the display panel 110.

While the normal area NA and the one or more optical areas (OA1 and/or OA2) included in the display area DA have a common function of allowing images to be displayed, a difference is that the normal area NA may be an area where a light transmissive structure need not be implemented, but the one or more optical areas (OA1 and/or OA2) may be areas where a light transmissive structure need be implemented. Thus, in one or more aspects, the normal area NA may be an area where a light transmissive structure is not implemented or included, and the one or more optical areas (OA1 and/or OA2) may be areas in which a light transmissive structure is implemented or included.

In one or more aspects, the one or more optical areas (OA1 and/or OA2) may have a transmittance greater than or equal to a predetermined level, i.e., a relatively high transmittance, and the normal area NA may have a transmittance less than the predetermined level or not have light transmittance.

For example, the one or more optical areas (OA1 and/or OA2) may have a resolution, a subpixel arrangement structure, a number of subpixels per unit area, an electrode structure, a line structure, an electrode arrangement structure, a line arrangement structure, and/or the like different from that/those of the normal area NA.

For example, the number of subpixels per unit area in the one or more optical areas (OA1 and/or OA2) may be less than the number of subpixels per unit area in the normal area NA.

For example, the resolution of the one or more optical areas (OA1 and/or OA2) may be lower than that of the normal area NA.

Here, the number of subpixels per unit area may be a unit for measuring resolution, for example, referred to as pixels (or subpixels) per inch (PPI), which represents the number of pixels (or subpixels) within 1 inch. Pixels per inch (PPI), also known as pixel density, refers to the number of pixels within a given inch on a display.

For example, the number of subpixels per unit area in the first optical areas OA1 may be less than the number of subpixels per unit area in the normal area NA.

For example, the number of subpixels per unit area in the second optical areas OA2 may be greater than or equal to the number of subpixels per unit area in the first optical areas OA1.

Herein, in examples where the display device 100 has a structure in which the first optical electronic device 11 such as a camera, and the like, is located under, or in a lower portion of, the display panel 110 without being exposed to the outside, such a display device 100 may be referred to as a display in which under-display camera (UDC) technology is applied.

According to these examples, the display device 100 can have an advantage of avoiding the size reduction of the display area DA because a notch or a camera hole for exposing a camera need not be formed in the display panel 110.

Indeed, since a notch or a camera hole for camera exposure need not be formed in the display panel 110, the display device 100 can provide further advantages of reducing the size of a bezel area, and improving the degree of freedom in design because such limitations to the design are removed.

Even when the one or more optical electronic devices (11 and/or 12) are located on the back of (e.g., under, or in a lower portion of) the display panel 110 of the display device 100 (e.g., hidden or not to be exposed to the outside), the one or more optical electronic devices (11 and/or 12) are needed to perform predefined functionalities by normally receiving or detecting light.

Further, in the display device 100, even when one or more optical electronic devices (11 and/or 12) are located on the back of (e.g., under, or in a lower portion of) the display panel 110 to be hidden and located to be overlap the display area DA, it is necessary for image display to be normally performed in the one or more optical areas (OA1 and/or OA2) overlapping the one or more optical electronic devices (11 and/or 12) in the display area DA. Thus, in one or more examples, even when one or more optical electronic devices (11 and/or 12) are located on the back of the display panel, images can be displayed in a normal manner (e.g., without reduction in image quality) in the one or more optical areas (OA1 and/or OA2) overlapping the one or more optical electronic devices (11 and/or 12) in the display area DA.

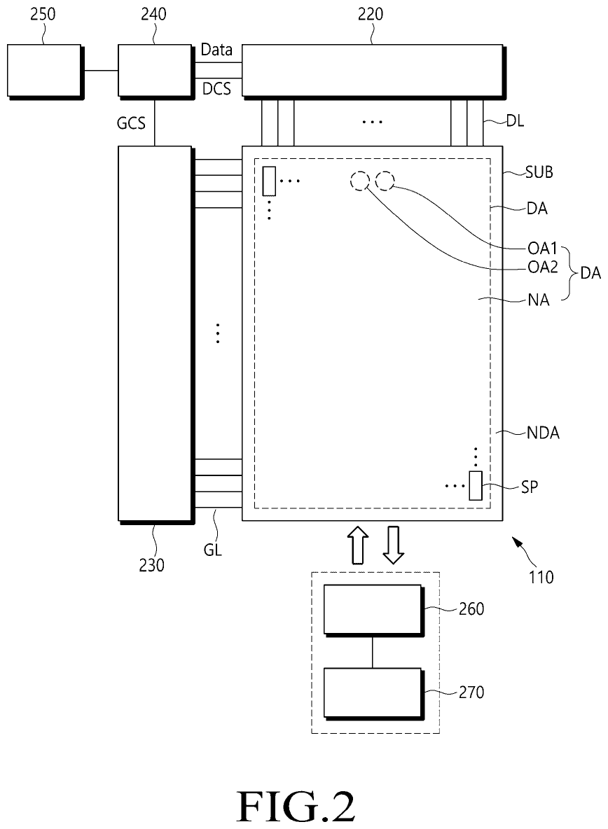

FIG. 2 illustrates an example system configuration of the display device 100 according to aspects of the present disclosure.

Referring to FIG. 2, the display device 100 may include the display panel 110 and a display driving circuit as components for displaying one or more images.

The display driving circuit may be a circuit for driving the display panel 110, and include a data driving circuit 220, a gate driving circuit 230, a display controller 240, and other circuit components.

The display panel 110 may include a display area DA configured to allow one or more images to be displayed and a non-display area NDA in which an image is not displayed.

The non-display area NDA may be an area outside of the display area DA, and may also be referred to as an edge area or a bezel area.

All or a portion of the non-display area NDA may be an area visible from the front surface of the display device 100, or an area that is bent and invisible from the front surface of the display device 100.

The display panel 110 may include a substrate SUB and a plurality of subpixels SP disposed on the substrate SUB.

The display panel 110 may further include various types of signal lines to drive the plurality of subpixels SP.

In one or more aspects, the display device 100 may be a liquid crystal display device, or a self-emission display device in which light is emitted from the display panel itself, or the like.

In an example where the display device 100 is a self-emission display device, each of the plurality of subpixels SP may include a light emitting element.

For example, the display device 100 according to aspects of the present disclosure may be an organic light emitting display device in which light emitting elements ED are implemented using organic light emitting diodes (OLED).

In another example, the display device 100 according to aspects of the present disclosure may be an inorganic light emitting display device in which light emitting elements are implemented using inorganic material-based light emitting diodes.

In further another example, the display device 100 according to aspects of the present disclosure may be a quantum dot display device implemented with quantum dots, which are self-emission semiconductor crystals, as light emitting elements.

The structure of each of the plurality of subpixels SP may be differently configured or designed according to types of the display devices 100.

For example, in an example where the display device 100 is a self-emission display device including self-emission subpixels SP, each subpixel SP may include a self-emission light emitting element, one or more transistors, and one or more capacitors.

In one or more aspects, various types of signal lines arranged in the display device 100 may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect one another.

Each of the plurality of data lines DL may be configured to extend in a first direction.

Each of the plurality of gate lines GL may be configured to extend in a second direction.

For example, the first direction may be the column or vertical direction, and the second direction may be the row or horizontal direction.

In another example, the first direction may be the row or horizontal direction, and the second direction may be the column or vertical direction.

The data driving circuit 220 may be a circuit for driving the plurality of data lines DL, and can supply data signals to the plurality of data lines DL.

The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive image data input from a host system 250 and supply image data Data based on the input image data to the data driving circuit 220.

The data driving circuit 220 can supply data signals to the plurality of data lines DL according to driving timing control of the display controller 240.

The data driving circuit 220 can receive digital image data Data from the display controller 240, convert the received image data Data into analog data signals, and output the resulting analog data signals to the plurality of data lines DL.

The gate driving circuit 230 can supply gate signals to the plurality of gate lines GL according to timing control of the display controller 240.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more aspects, the gate driving circuit 230 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique.

In one or more aspects, the gate driving circuit 230 may be disposed in the non-display area NDA of the display panel 110 by a gate-in-panel (GIP) technique.

The gate driving circuit 230 may be disposed on the substrate, or connected to the substrate.

In an example where the gate driving circuit 230 is implemented by the GIP technique, the gate driving circuit 230 may be disposed in the non-display area NDA of the substrate.

The gate driving circuit 230 may be connected to the substrate in an example where the gate driving circuit 230 is implemented by the chip-on-glass (COG) technique, the chip-on-film (COF) technique, or the like.

In one or more aspects, at least one of the data driving circuit 220 and the gate driving circuit 230 may be disposed in the display area DA of the display panel 110.

For example, at least one of the data driving circuit 220 and the gate driving circuit 230 may be configured not to overlap with subpixels SP, or configured to overlap with one or more, or all, of the subpixels SP, or at least respective one or more portions of one or more subpixels.

In one or more aspects, the data driving circuit 220 may be disposed in, and/or electrically connected to, but not limited to, one side or portion (e.g., an upper edge or a lower edge) of the display panel 110.

In one or more aspects, the data driving circuit 220 may be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

In one or more aspects, the gate driving circuit 230 may be located in, and/or electrically connected to, but not limited to, one side or portion (e.g., a left edge or a right edge) of the display panel 110.

In one or more aspects, the gate driving circuit 230 may be located in, and/or electrically connected to, but not limited to, two sides or portions (e.g., a left edge and a right edge) of the display panel 110 or at least two of four sides or portions (e.g., an upper edge, a lower edge, the left edge, and the right edge) of the display panel 110 according to driving schemes, panel design schemes, or the like.

The display controller 240 may be implemented in a separate component from the data driving circuit 220, or incorporated in the data driving circuit 220 and thus implemented in an integrated circuit.

The display controller 240 may be a timing controller used in the typical display technology or a controller or a control device capable of performing other control functions in addition to the function of the typical timing controller. In one or more embodiments, the display controller 240 may be a controller or a control device different from the timing controller, or a circuitry or a component included in the controller or the control device.

The display controller 240 may be implemented with various circuits or electronic components such as an integrated circuit (IC), a field programmable gate array (FPGA), an application specific integrated circuit (ASIC), a processor, and/or the like.

The display controller 240 may be mounted on a printed circuit board, a flexible printed circuit, and/or the like and be electrically connected to the gate driving circuit 230 and the data driving circuit 220 through the printed circuit board, flexible printed circuit, and/or the like.

The display controller 240 can transmit signals to, and receive signals from, the data driving circuit 220 via one or more predefined interfaces.

For example, such interfaces may include a low voltage differential signaling (LVDS) interface, an embedded clock point-point interface (EPI), a serial peripheral interface (SPI), and the like.

In one or more aspects, in order to further provide a touch sensing function, as well as an image display function, the display device 100 may include a touch sensor, and a touch sensing circuit capable of detecting whether a touch is applied by a touch object such as a finger, a pen, or the like, or detecting a location of the touch (or touch coordinates), by sensing the touch sensor.

The touch sensing circuit may include a touch driving circuit 260 capable of generating and providing touch sensing data by driving and sensing the touch sensor, a touch controller 270 capable of detecting whether a touch is applied or detecting a location of the touch (or touch coordinates) using the touch sensing data, and one or more other components.

The touch sensor may include a plurality of touch electrodes.

The touch sensor may further include a plurality of touch lines for electrically connecting the plurality of touch electrodes to the touch driving circuit 260.

The touch sensor may be implemented in the form of a touch panel outside of the display panel 110 or be integrated inside of the display panel 110.

In the example where the touch sensor is implemented in the form of the touch panel located outside of the display panel 110, such a touch sensor may be referred to as an add-on type.

In the example where the add-on type of touch sensor is disposed in the display device 100, the touch panel and the display panel 110 may be separately manufactured and combined in an assembly process.

The add-on type of touch panel may include a touch panel substrate and a plurality of touch electrodes disposed on the touch panel substrate.

In the example where the touch sensor is integrated inside of the display panel 110, the touch sensor may be formed on the substrate SUB together with signal lines and electrodes related to display driving during a process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrode and an object such as a finger, a pen, and/or the like.

According to the self-capacitance sensing method, each of a plurality of touch electrodes can serve as both a driving touch electrode and a sensing touch electrode.

The touch driving circuit 260 can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes.

According to the mutual-capacitance sensing technique, a plurality of touch electrodes may be divided into driving touch electrodes and sensing touch electrodes.

The touch driving circuit 260 can drive the driving touch electrodes and sense the sensing touch electrodes.

The touch driving circuit 260 and the touch controller 270 included in the touch sensing circuit may be implemented in separate devices or in a single device.

Further, the touch driving circuit 260 and the data driving circuit 220 may be implemented in separate devices or in a single device.

The display device 100 may further include a power supply circuit for supplying various types of power to the display driving circuit and/or the touch sensing circuit.

In some aspects, the display device 100 may be a mobile terminal such as a smart phone, a tablet, or the like, or a monitor, a television (TV), or the like. Such devices may be configured in various types, sizes, and shapes. The display device 100 according to aspects of the present disclosure are not limited thereto, and may include various types, sizes, and shapes configured to display information or images.

As described above, the display area DA of the display panel 110 may include the normal area NA and the one or more optical areas (OA1 and/or OA2) as illustrated in FIG. 1.

The normal area NA and the one or more optical areas (OA1 and/or OA2) may be areas configured to allow images to be displayed.

It should be noted here that the normal area NA may be an area in which a light transmission structure need not be implemented, and the one or more optical areas (OA1 and/or OA2) may be areas in which a light transmission structure need be implemented.

As discussed above, even though the display area DA of the display panel 110 may include the one or more optical areas (OA1 and/or OA2) together with the normal area NA, for convenience of description, discussions that follow are provided based on examples where the display area DA includes both the first and second optical areas (OA1 and OA2).

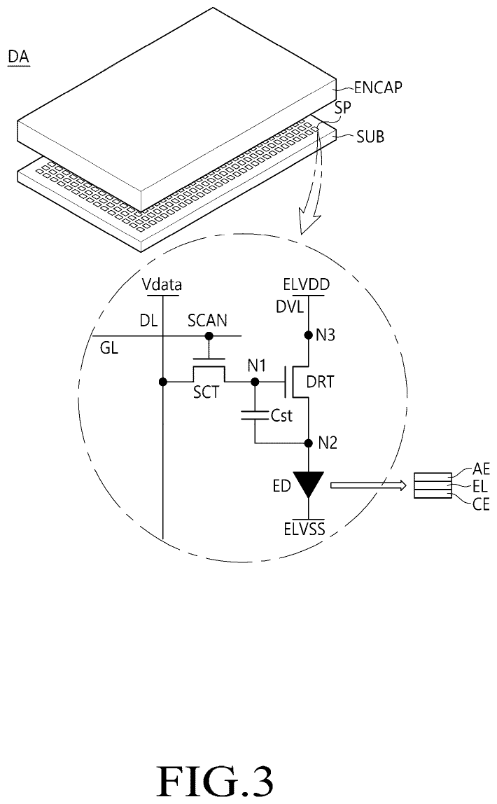

FIG. 3 illustrates an example equivalent circuit of a subpixel SP in the display panel 110 according to aspects of the present disclosure.

Each of subpixels SP disposed in the normal area NA, the first optical area OA1, and the second optical area OA2 included in the display area DA of the display panel 110 may include a light emitting element ED, a driving transistor DRT for driving the light emitting element ED, a scan transistor SCT for passing a data voltage Vdata to a first node N1 of the driving transistor DRT, a storage capacitor Cst for maintaining a voltage at an approximate constant level during one frame, and the like.

The driving transistor DRT may include the first node N1 to which a data voltage is applied, a second node N2 electrically connected to the light emitting element ED, and a third node N3 to which a driving voltage ELVDD delivered through a driving voltage line DVL is applied.

In the driving transistor DRT, the first node N1 may be a gate node, the second node N2 may be a source node or a drain node, and the third node N3 may be the drain node or the source node.

The light emitting element ED may include a first electrode layer AE, an emission layer EL, and a second electrode layer CE.

The first electrode layer AE may be a pixel electrode disposed in each subpixel SP, and may be electrically connected to the second node N2 of the driving transistor DRT of each subpixel SP.

The second electrode layer CE may be a common electrode commonly disposed in all or some of a plurality of subpixels SP. For example, a base voltage ELVSS may be applied to the second electrode layer CE.

For example, the first electrode layer AE may be a pixel electrode, and the second electrode layer CE may be a common electrode.

In another example, the first electrode layer AE may be the common electrode, and the second electrode layer CE may be the pixel electrode.

Hereinafter, for convenience of explanation, discussions are provided based on examples where the first electrode layer AE is a pixel electrode and the second electrode layer CE is a common electrode.

In one or more aspects, the light emitting element ED may be an organic light emitting diode (OLED), an inorganic light emitting diode, a quantum dot (QD) light emitting element, or the like.

In an example where the light emitting element ED is an organic light emitting diode, an emission layer EL of the light emitting element ED may include an organic emission layer containing an organic material.

The scan transistor SCT can be turned on and off by a scan signal SCAN, which is a gate signal applied through a gate line GL, and be electrically connected between the first node N1 of the driving transistor DRT and a data line DL.

The storage capacitor Cst may be electrically connected between the first node N1 and the second node N2 of the driving transistor DRT.

Each subpixel SP may include two transistors (2T: DRT and SCT) and one capacitor (1C: Cst) (which may be referred to as a “2T1C structure”) as illustrated in FIG. 3, and in some cases, may further include one or more transistors, and/or further include one or more capacitors.

The storage capacitor Cst may be an external capacitor intentionally designed to be located outside of the driving transistor DRT, other than an internal capacitor, such as a parasitic capacitor (e.g., a Cgs or a Cgd), that may be formed between the first node N1 and the second node N2 of the driving transistor DRT.

In one or more aspects, each of the driving transistor DRT and the scan transistor SCT may be an n-type transistor, or a p-type transistor.

In one or more aspects, each of the driving transistor DRT and the scan transistor SCT may be a low-temperature polycrystalline silicon transistor.

However, example embodiments of the present disclosure are not limited thereto. For example, at least one of the driving transistor DRT and the scan transistor SCT may be an oxide thin film transistor.

Since circuit elements (in particular, a light emitting element ED implemented with an organic light emitting diode including an organic material) included in each subpixel SP are vulnerable to external moisture or oxygen, an encapsulation layer ENCAP may be configured to cover the circuit elements (e.g., the light emitting element ED) in order to prevent external moisture or oxygen from penetrating into such circuit elements.

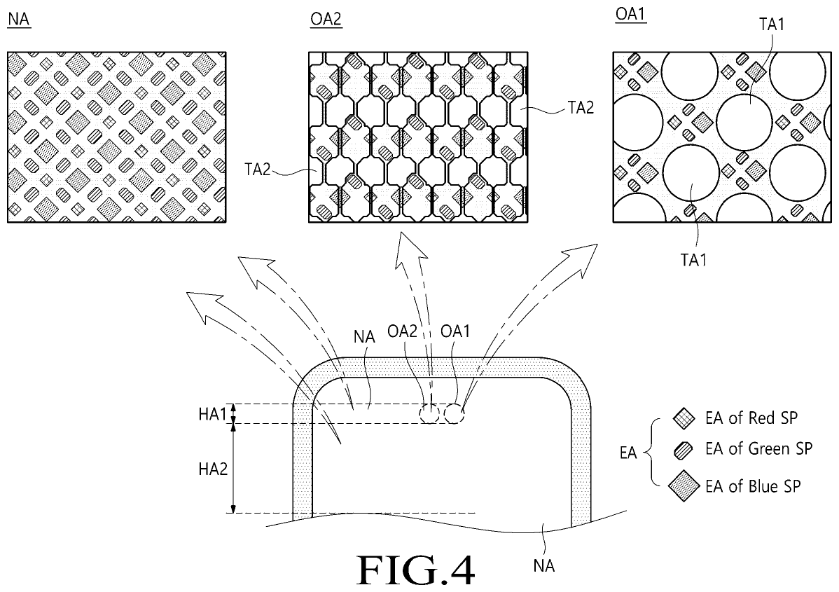

FIG. 4 illustrates arrangements of subpixels SP in example three areas (NA, OA1, and OA2) included in the display area of the display device 100 according to aspects of the present disclosure.

Referring to FIG. 4, in one or more example embodiments, a plurality of subpixels SP may be disposed in each of the normal area NA, the first optical area OA1, and the second optical area OA2 included in the display area DA.

The plurality of subpixels SP may include, for example, a red subpixel (Red SP) emitting red light, a green subpixel (Green SP) emitting green light, and a blue subpixel (Blue SP) emitting blue light.

Accordingly, each of the normal area NA, the first optical area OA1, and the second optical area OA2 may include one or more light emitting areas EA of one or more red subpixels (Red SP), and one or more light emitting areas EA of one or more green subpixels (Green SP), and one or more light emitting areas EA of one or more blue subpixels (Blue SP).

Referring to FIG. 4, the normal area NA may not include a light transmissive structure, but may include light emitting areas EA.

In one or more aspects, each of the first optical area OA1 and the second optical area OA2 may be needed to include a light transmissive structure, as well as light emitting areas EA.

Accordingly, in one or more aspects, the first optical area OA1 may include one or more light emitting areas EA and one or more first transmissive areas TA1, and the second optical area OA2 may include one or more light emitting areas EA and one or more second transmissive areas TA2.

Light emitting areas EA and transmissive areas (TA1 and TA2) may be distinct from each other based on whether light is allowed to be transmitted or not.

For example, light emitting areas EA may be areas not allowing light to be transmitted (e.g., not allowing light to be transmitted to the back of the display panel), and transmissive areas (TA1 and/or TA2) may be areas allowing light to be transmitted (e.g., allowing light to be transmitted to the back of the display panel).

Light emitting areas EA and transmissive areas (TA1 and TA2) may be also distinct from each other based on whether a second electrode layer CE (e.g., the second electrode layer CE of FIG. 3) is disposed or not.

For example, while the second electrode layer CE may be disposed in the light emitting areas EA, the second electrode layer CE may not be disposed in the transmissive areas (TA1 and TA2).

In one or more aspects, a light shield layer may be disposed in light emitting areas EA, and a light shield layer may not be disposed in transmissive areas (TA1 and/or TA2).

Since the first optical area OA1 includes first transmissive areas TA1 and the second optical area OA2 includes second transmissive areas TA2, both the first optical area OA1 and the second optical area OA2 may be areas configured to allow light to be transmitted.

A transmittance (a degree of transmission) of the first optical area OA1 and a transmittance (a degree of transmission) of the second optical area OA2 may be substantially the same.

Herein, substantially the same may mean a degree of being considered as being equivalent to each other taking into account minute differences due to errors in the process of manufacturing the display panel 110 or display device 100.

According to this definition, first transmissive areas TA1 of the first optical area OA1 and second transmissive areas TA2 of the second optical area OA2 may have substantially the same shape or size.

In one or more aspects, even when first transmissive areas TA1 of the first optical area OA1 and second transmissive areas TA2 of the second optical area OA2 have different shapes or sizes, a ratio of the first transmissive areas TA1 to the first optical area OA1 and a ratio of the second transmissive areas TA2 to the second optical area OA2 may be substantially the same.

However, example embodiments of the present disclosure are not limited thereto. For example, a transmittance (a degree of transmission) of the first optical area OA1 and a transmittance (a degree of transmission) of the second optical area OA2 may be different from each other.

In this implementation, first transmissive areas TA1 of the first optical area OA1 and second transmissive areas TA2 of the second optical area OA2 may have different shapes or sizes.

In one or more aspects, even when first transmissive areas TA1 of the first optical area OA1 and second transmissive areas TA2 of the second optical area OA2 have substantially the same shape or size, a ratio of the first transmissive areas TA1 to the first optical area OA1 and a ratio of the second transmissive areas TA2 to the second optical area OA2 may be different from each other.

For example, in an example where the first optical electronic device 11 overlapping with the first optical area OA1 is a camera, and the second optical electronic device 12 overlapping with the second optical area OA2 is a sensor for detecting images, the camera may need a greater amount of light than the sensor.

In this example, a transmittance (a degree of transmission) of the first optical area OA1 may be greater than a transmittance (a degree of transmission) of the second optical area OA2.

In this implementation, all or each of first transmissive areas TA1 of the first optical area OA1 may have an area greater than all or each of second transmissive areas TA2 of the second optical area OA2.

In one or more aspects, even when first transmissive areas TA1 of the first optical area OA1 and second transmissive areas TA2 of the second optical area OA2 have substantially the same size, a ratio of the first transmissive areas TA1 to the first optical area OA1 may be greater than a ratio of the second transmissive areas TA2 to the second optical area OA2.

In one or more aspects, as shown in FIG. 4, first transmissive areas TA1 of the first optical area OA1 may have circular shapes in a plan view, but example embodiments of the present disclosure for shapes of the first transmissive areas TA1 are not limited thereto.

For example, the first transmissive areas TA1 of the first optical area OA1 may have octagonal shapes in a plan view, or may have elliptical or polygonal shapes.

As discussed above, by changing the shape of the first transmissive areas TA1, the transmittance of the first optical area OA1 can be adjusted, and the area or size of light emitting areas of the first optical area OA1 can be adjusted.

Hereinafter, for convenience of explanation, discussions are provided based on examples where the transmittance (the degree of transmission) of the first optical area OA1 is greater than that of the second optical area OA2.

Further, as shown in FIG. 4, transmissive areas (TA1 and TA2) may be referred to as transparent areas, and transmittance may also be referred to as transparency.

In discussions that follow, as shown in FIG. 4, it is assumed that the first optical area OA1 and the second optical area OA2 are located at an upper portion of the display area DA of the display panel 110, and are disposed side by side left and right.

Referring to FIG. 4, a horizontal display area where the first optical area OA1 and the second optical area OA2 are disposed may be referred to as a first horizontal display area HA1, and a horizontal display area where the first optical area OA1 and the second optical area OA2 are not disposed may be referred to as a second horizontal display area HA2.

Referring to FIG. 4, the first horizontal display area HA1 may include a portion of the normal area NA, the first optical area OA1, and the second optical area OA2.

The second horizontal display area HA2 may include only the normal area NA.

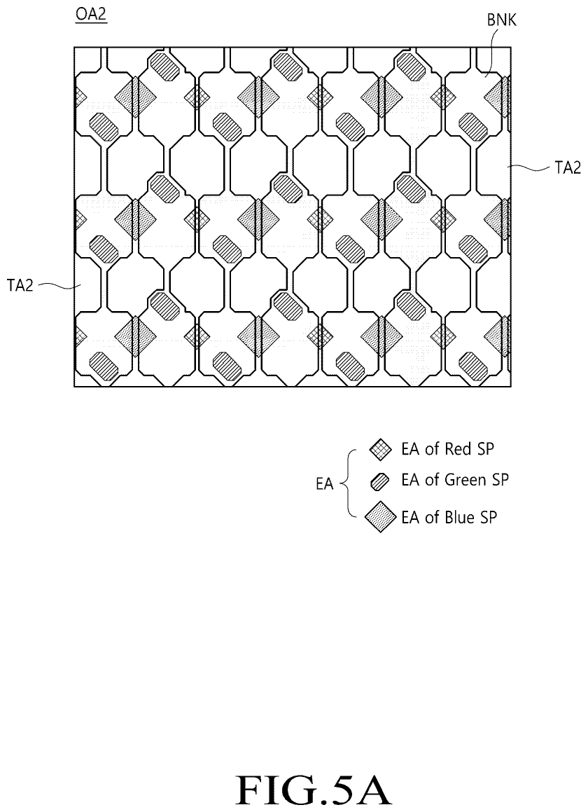

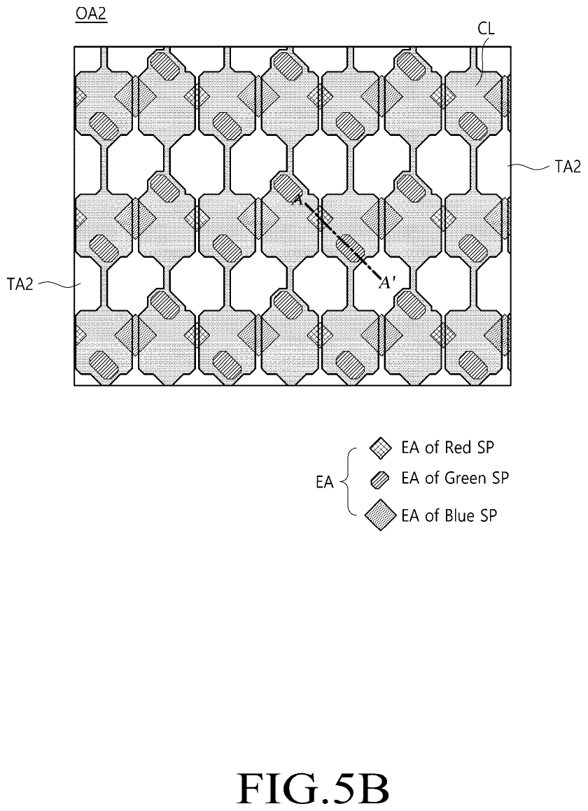

FIGS. 5A and 5B are example enlarged plan views of the second optical area OA2 of FIG. 4 according to aspects of the present disclosure.

Referring to FIGS. 5A and 5B, the second optical area OA2 may include subpixels SP arranged in a zigzag shape.

Each of the subpixels SP may be one subpixel SP among a red subpixel (Red SP), a green subpixel (Green SP), and a blue subpixel (Blue SP). One unit pixel may be implemented by including two or more of the red subpixel (Red SP), the green subpixel (Green SP), and the blue subpixel (Blue SP).

In one or more aspects, each of the plurality of subpixels SP may further include a white subpixel.

In one or more aspects, two subpixels may be implemented as one pixel using a subpixel rendering algorithm.

In these examples, such insufficient color representation in each of the pixel groups may be compensated for based on an average value of corresponding color data of neighboring pixels through a subpixel rendering algorithm.

It should be noted that the configuration of the second transmissive areas TA2 of FIGS. 5A and 5B may be substantially the same as the configuration of the second transmissive areas TA2 in FIG. 4.

FIG. 5A is a plan view illustrating an example where a cover layer CL is not located on the bank layer BNK, and FIG. 5B is a plan view illustrating an example where a cover layer CL is located on the bank layer BNK.

The cover layer CL may be referred to as a coating layer CL1 or a dummy emission layer CL2, which will be discussed later.

Referring to FIG. 5B, the cover layer CL may cover at least a portion of the bank layer BNK.

For example, the cover layer CL may cover all or at least part of the bank layer BNK in the second optical area OA2.

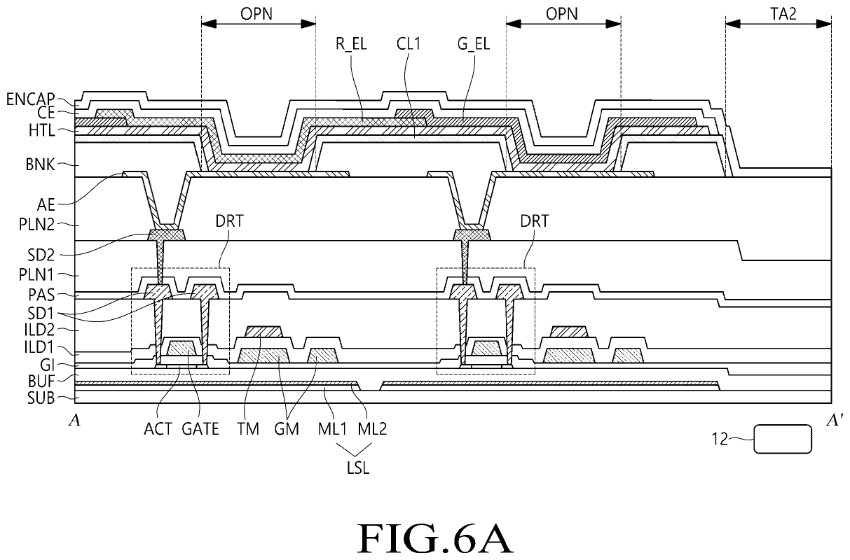

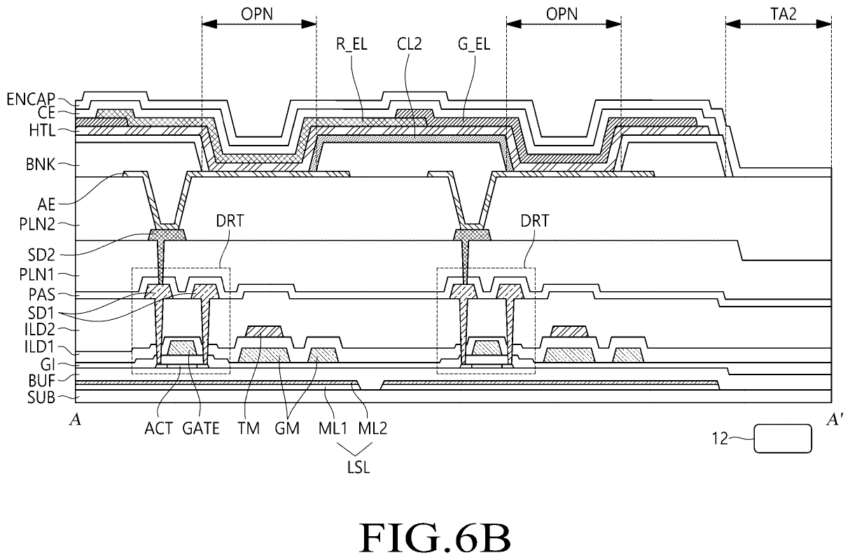

The cover layer CL is discussed in detail below with reference to FIGS. 6A and 6B.

FIGS. 6A and 6B are example cross-sectional views taken along line A-A′h of FIG. 5B according to aspects of the present disclosure.

A cover layer CL in FIG. 6A may be referred to as a coating layer CL1, and a cover layer CL in FIG. 6B may be referred to as a dummy emission layer CL2.

Referring to FIGS. 6A and 6B, various types of patterns (ACT, SD1, GATE, and the like) for forming one or more transistors such as a driving transistor DRT, a scan transistor SCT, and the like, various types of insulating layers (BUF, GI, ILD1, ILD2, PAS, and the like), and various types of metal patterns (TM, GM, ML1, ML2, and the like) may be disposed on or over a substrate SUB.

Referring to FIGS. 6A and 6B, a buffer layer BUF may be disposed on the substrate SUB.

A first metal layer ML1 and a second metal layer ML2 may be disposed on the substrate SUB.

For example, the first metal layer ML1 and the second metal layer ML2 may be light shield layers LSL configured to shield light.

The buffer layer BUF may be disposed on the first metal layer ML1 and the second metal layer ML2.

An active layer ACT of a driving transistor DRT may be disposed on the buffer layer BUF.

A gate insulating layer GI may be configured to cover the active layer ACT.

The gate electrode GATE of the driving transistor DRT may be disposed on the gate insulating layer GI.

In one or more aspects, a gate material layer GM may be disposed on the gate insulating layer GI along with the gate electrode layer GATE of the driving transistor DRT at a location different from an area where the driving transistor DRT is formed.

A first interlayer insulating layer ILD1 may be configured to cover the gate electrode layer GATE and the gate material layer GM.

A metal pattern TM may be disposed on the first interlayer insulating layer ILD1.

The metal pattern TM may be located at a location different from the area where the driving transistor DRT is formed.

A second interlayer insulating layer ILD2 may be configured to cover the metal pattern TM on the first interlayer insulating layer ILD1.

Two first source-drain electrode pattern layers SD1 may be disposed on the second interlayer insulating layer ILD2.

One of the two first source-drain electrode pattern layers SD1 may be the source node of the driving transistor DRT, and the other thereof may be the drain node of the driving transistor DRT.

The two first source-drain electrode pattern layers SD1 may be electrically connected to respective portions (e.g., a first side and a second opposing side) of the active layer ACT through a contact hole in the second interlayer insulating layer ILD2, the first interlayer insulating layer ILD1 and the gate insulating layer GI.

A portion of the active layer ACT, which overlaps with the gate electrode layer GATE, may act as a channel region.

For example, one of the two first source-drain electrode pattern layers SD1 may be connected to one side of the channel region of the active layer ACT, and the other one of the two first source-drain electrode pattern layers SD1 may be connected to the other side of the channel region of the active layer ACT.

A passivation layer PAS may be configured to cover the two first source-drain electrode pattern layers SD1.

At least one planarization layer PLN may be disposed on the passivation layer PAS.

The at least one planarization layer PLN may include a first planarization layer PLN1 and a second planarization layer PLN2.

The first planarization layer PLN1 may be disposed on the passivation layer PAS.

A second source-drain electrode pattern layer SD2 may be disposed on the first planarization layer PLN1.

The second source-drain electrode pattern layer SD2 may be connected to one of the two first source-drain electrode pattern layers SD1 (which may correspond to the second node N2 of the driving transistor DRT in the subpixel SP of FIG. 3) through a contact hole in the first planarization layer PLN1.

The second planarization layer PLN2 may be configured to cover the second source-drain electrode pattern layer SD2.

A light emitting element ED may be disposed on the second planarization layer PLN2.

The light emitting element ED may have a stack structure configured with a stack of layers as discussed below. A first electrode layer AE may be disposed on the second planarization layer PLN2.

The first electrode layer AE may include a material with a relatively high work function.

The first electrode layer AE may include, for example, a transparent conductive oxide, such as indium tin oxide (ITO), indium zinc oxide (IZO), zinc oxide (ZnO), aluminum zinc oxide (AZO), indium oxide (In₂O₃), tin oxide (SnO₂), or the like, but example embodiments of the present disclosure are not limited thereto.

The first electrode layer AE may be electrically connected to the second source-drain electrode pattern layer SD2 through a contact hole in the second planarization layer PLN2.

A bank layer BNK may be configured to cover a portion of the first electrode layer AE.

A portion of the bank layer BNK corresponding to a light emitting area EA of a corresponding subpixel SP may be opened to form an open area OPN.

For example, a portion of the first electrode layer AE may be exposed to the open area OPN of the bank layer BNK.

An emission layer EL may be located on side surfaces of the bank layer BNK and in the open area OPN of the bank layer BNK.

At least a portion of the emission layer EL may be located between adjacent open areas OPN of the bank layer BNK.

In the open area OPN of the bank layer BNK, the emission layer EL may be disposed on the first electrode layer AE.

A second electrode layer CE may be disposed on the emission layer EL.

The second electrode layer CE may include a material with a relatively low work function, for example, a metal, an alloy, an electroconductive compound, or a mixture of two or more thereof.

For example, a transmissive electrode as the second electrode layer CE may be obtained by forming, in the form of a thin film, lithium (Li), magnesium (Mg), aluminum (Al), aluminum-lithium (Al—Li), calcium (Ca), magnesium-indium (Mg—In), magnesium-silver (Mg—Ag), and/or the like.

In this regard, various modifications may be made, such as forming transmissive electrodes using ITO or IZO in a structure where light emitting elements are configured to emit light to the front of the display device 100 with a top emission structure.

The emission layer EL may include an organic material.

The emission layer EL may include a red mission layer R_EL disposed in a red subpixel Red SP, a green mission layer G_EL disposed in a green subpixel Green SP, and a blue mission layer B_EL disposed in a blue subpixel Blue SP.

For example, wavelengths of light emitted from the emission layers (R_EL, G_EL, and B_EL) may be, in a descending length order, the red emission layer R_EL, the green emission layer G_EL, and the blue emission layer B_EL.

A hole transport layer HTL may be disposed between the emission layer EL and the first electrode layer AE.

Adjacent emission layers EL may partially overlap with each other on the bank layer BNK.

The red mission layer R_EL may include a red host and a red dopant.

The red host may use Alq3, CBP, PVK, AND, TCTA, TPBI, TBADN, E3, DSA, or a mixture of two or more thereof, but example embodiments of the present disclosure are not limited thereto.

The red dopant may use PtOEP, Ir(piq)₃, Btp₂Ir(acac), Ir(2-phq)₂(acac), Ir(2-phq)₃, Ir(flq)₂(acac), Ir(fliq)₂(acac), or compounds containing DCM or DCJTB, but example embodiments of the present disclosure are not limited thereto.

The green mission layer G_EL may include a green host and a green dopant.

The green host may use Alq3, CBP, PVK, AND, TCTA, TPBI, TBADN, E3, DSA, or a mixture of two or more thereof, but example embodiments of the present disclosure are not limited thereto.

The green dopant may use Ir(ppy)₃ tris(2-phenylpyridine) iridium, Ir(ppy)₂(acac)(Bis(2-phenylpyridine)(Acetylacetonato)iridium(III), Ir(mppy)₃ (tris(2-(4-tolyl)phenylpiridine)iridium, C545T 10-(2benzothiazolyl)-1,1,7,7-tetramethyl-2,3,6,7-tetrahydro-1H,5H,11H-[1]benzopyrano [6,7,8-ij]-quinolizin11-one, or the like, but example embodiments of the present disclosure are not limited thereto.

The blue mission layer B_EL may include a blue host and a blue dopant.

The blue host may use Alq3, CBP(4,4′h-N,N′h-dicabazole-biphenyl), PVK(poly(n-vinylcabazole), ADN(9,10-di(naphthalene-2-yl)anthracene), TCTA, TPBI(1,3,5-tris(N-phenylbenzimidazole-2-yl)benzene), TBADN(3-tert-butyl-9,10-di(naphth-2-yl) anthracene), E3, DSA(distyrylarylene), or a mixture of two or more thereof, but example embodiments of the present disclosure are not limited thereto.

The blue dopant may use compounds containing F₂Irpic, (F₂ppy)₂Ir(tmd), Ir(dfppz)₃, ter-fluorene, DPAVBi(4,4′h-bis(4diphenylaminostyryl)biphenyl, TBPe, and/or the like, but example embodiments of the present disclosure are not limited thereto.

As described above, as some layers included in the stack structure of the light emitting element ED, the first electrode layer AE, the emission layer EL, and the second electrode layer CE have been discussed.

Hereinafter, a stack structure of a second transmissive area TA2 in the second optical area OA2 is described in detail.

A second electrode layer CE may be disposed in the normal area NA and the non-transmissive area of the second optical area OA2, but the second electrode layer CE may not be disposed in the second transmissive area TA2 of the second optical area OA2.

For example, the second transmissive area TA2 of the second optical area OA2 may correspond to an opening (or an open area) of the second electrode layer CE.

In one or more aspects, a light shield layer LSL including at least one of a first metal layer ML1 and a second metal layer ML2 may be disposed in the normal area NA and the non-transmissive area of the second optical area OA2, but a light shield layer LSL may not be disposed in the second transmissive area TA2 of the second optical area OA2.

In one or more aspects, the substrate SUB and various types of insulating layers (BUF, GI, ILD1, ILD2, PAS, PLN1, PLN2, BNK, and ENCAP) disposed in the normal area NA and the non-transmissive area of the second optical area OA2 may be equally disposed in the second transmissive area TA2 of the second optical area OA2.

For example, among elements or layers disposed in the normal area NA and the non-transmissive area of the second optical area OA2, material layers with electrical properties (e.g., a metal material layer, a semiconductor layer, and the like) except for the insulating layers may not be disposed in the second transmissive area TA2 of the second optical area OA2.

For example, referring to FIGS. 6A and 6B, metal material layers (ML1, ML2, GATE, GM, TM, SD1, and SD2) and semiconductor layers (ACT) related to transistors may not be disposed in the second transmissive area TA2 of the second optical area OA2.

In one or more aspects, a first electrode layer AE and the second electrode layer CE included in a light emitting element ED may not be disposed in the second transmissive area TA2.

In one or more aspects, it should be noted that an emission layer EL included in the light emitting element ED may be disposed or may not be disposed in the second transmissive area TA2 according to a design requirement.

Thus, since the material layers with electrical properties (e.g., a metal material layer, a semiconductor layer, and the like) are not disposed in the second transmissive area TA2 of the second optical area OA2, the transmittance of the second transmissive area TA2 of the second optical area OA2 can be improved.

Therefore, the second optical electronic device 12 can receive light passing through the second transmissive area TA2 and perform predefined functions (e.g., detecting approaching objects or human bodies, detecting ambient light, or the like.

As discussed above, the stack structure of the second transmissive area TA2 of the second optical area OA2 has been discussed.

Hereinafter, a coating layer CL1 as a cover layer CL is described with reference to FIG. 6A.

In one or more aspects, a coating layer CL1 may be disposed on the bank layer BNK and configured to cover at least a portion of the bank layer BNK.

In this implementation, a second optical electronic device 12 may be disposed under the bank layer BNK and configured to overlap with at least a portion of the coating layer CL1.

The second optical electronic device 12 may be located on or under the substrate SUB. For simplicity, discussions are provided based on an example where the second optical electronic device 12 is located under the substrate SUB.

The second optical electronic device 12 may be an illumination sensor and may also be referred to as an ambient light sensor.

Details for the second optical electronic device 12 may be substantially the same as those of the second optical electronic device 12 described in FIG. 1.

In a coating material included in the coating layer CL1, a rate of absorbing light with wavelengths in the range of 495 nm to 570 nm, which is the wavelength range perceived as green by the human eye, may be higher than a rate of absorbing light with wavelengths other than wavelengths in the range of 495 nm to 570 nm.

For example, the coating material may be one or more of copper, zirconium, iron, nickel, NaWO₃, ZnO, or TiO₂.

FIG. 6A illustrates that the coating layer CL1 is located between a red subpixel (Red SP) and a green subpixel (Green SP), but the location of the coating layer CL1 may not necessarily limited to this. For example, the coating layer CL1 may be located between the green subpixel (Green SP) and a blue subpixel (Blue SP), or the blue subpixel (Blue SP) and the red subpixel (Red SP), or be disposed in a portion of the bank layer BNK other than a portion of the bank layer BNK between subpixels.

In the example where the coating layer CL1 covers a portion of the bank layer BNK between the red subpixel (Red SP) and the green subpixel (Green SP), when the red subpixel (Red SP) is driven, a corresponding green emission layer G_EL may be prevented from emitting light downwards (hereinafter, which may be referred to as “bottom emission”) by the lateral leakage current LLC flowing along a hole transport layer HTL of a light emitting element ED included in the red subpixel (Red SP).

That is, since the coating layer CL1 includes a material capable of absorbing green light at a higher rate than light in other wavelength bands, green light emitted downwards by the lateral leakage current LLC can be absorbed by the coating layer CL1.

In this situation, the bottom emission may be a phenomenon caused as a red emitting layer EL_R partially overlaps with the green emission layer G_EL on the coating layer CL1.

Therefore, an unintended detection operation of the second optical electronic device 12 by green light emitted by the green emission layer due to the lateral leakage current LLC can be prevented. Thereby, the reliability of the second optical electronic device 12 can be increased, and the performance of the second optical electronic device 12 for detecting external light can be improved.

When the red subpixel (Red SP) is driven, the lateral leakage current LLC may flow not only to the green subpixel (Green SP) but also to an adjacent blue subpixel (Blue SP), thereby, blue light may be emitted downwards. Thus, unintended detection operations of the second optical electronic device 12 due to the lateral leakage current LLC according to example embodiments of the present disclosure are not limited to the bottom emission caused by the green emission layer.

However, unlike other subpixels, since the green subpixel (Green SP) has a high delay characteristic and produces a large amount of green light, the coating layer CL1 may be desirable to cover a portion of the bank layer BNK between the red subpixel (Red SP) and the green subpixel (Green SP).

In one or more aspects, blue light emitted downwards may be absorbed by covering a portion of the bank layer BNK between the red subpixel (Red SP) and the blue subpixel (Blue SP) with the coating layer CL1 including a material capable of absorbing blue light at a higher rate than light in other wavelength bands.

In one or more aspects, materials included in the coating layer CL1 are not limited to the material capable of absorbing green light or blue light at a high rate, and may be a material capable of absorbing red light at a high rate.

Referring to FIG. 6B, a dummy emission layer CL2 covering at least a portion of the bank layer BNK may be disposed on the bank layer BNK.

That is, the dummy emission layer CL2 may be located between the bank layer BNK and the hole transport layer HTL.

A main emission layer EL may be located on the hole transport layer HTL.

The main emission layer EL of FIG. 6B may be substantially the same as the emission layer EL of FIG. 6A.

The main emission layer EL may be an emission layer emitting light by a current from a driving transistor DRT.

In contrast, the dummy emission layer CL2 may not be driven by the current from the driving transistor DRT, but may or may not emit light by light emitted from the main emission layer EL adjacent to the dummy emission layer CL2.

The light emitted from the dummy emission layer CL2 may have a wavelength smaller than the light emitted from at least one of the main emission layers EL adjacent to the dummy emission layer CL2.

For example, the light emitted from the dummy emission layer CL2 may have energy greater than the light emitted from at least one of the main emission layers EL adjacent to the dummy emission layer CL2.

Accordingly, when the main emission layer EL adjacent to the dummy emission layer CL2 emits light downwards due to lateral leakage current LLC, the light emitted downwards from the main emission layer EL may not affect the dummy emission layer CL2.

For examples, the dummy emission layer CL2 may not emit light due to the light emitted downwards from the main emission layer EL.

Since the dummy emission layer CL2 does not emit light due to the light emitted downwards from the main emission layer EL, the light emitted downwards may be blocked, and thereby, the second optical electronic device 12 overlapping with at least a portion of the dummy emission layer CL2 and located under the bank layer BNK can be prevented from performing an unintended detection operation due to the light emitted downwards from the main emission layer EL.

By preventing such an unintended detection operation, the reliability of the second optical electronic device 12 can be increased, and the performance of the second optical electronic device 12 for detecting external light can be improved.

The details of the second optical electronic device 12 in FIG. 6B may be substantially the same as the details of the second optical and electronic device 12 described in FIG. 1.

FIG. 6B illustrates the example where the dummy emission layer CL2 located on a portion of the bank layer BNK between the red subpixel (Red SP) and the green subpixel (Green SP) is a blue emission layer, but this is only an example and example embodiments of the present disclosure are not limited to this. For example, an emission layer of the dummy emission layer CL2 may include a different material depending on the color of a subpixel adjacent to the dummy emission layer CL2.

For example, when at least one of main emission layers EL adjacent to the dummy emission layer CL2 is a red emission layer or a green emission layer, the dummy emission layer CL2 may include the same material as the blue emission layer.

In another example, when at least one of main emission layers EL adjacent to the dummy emission layer CL2 is a red emission layer, the dummy emission layer CL2 may include the same material as the green emission layer.

However, unlike other subpixels, since the green subpixel (Green SP) has a high delay characteristic and produces a large amount of green light, the dummy emission layer CL2 may be desirable to cover a portion of the bank layer BNK between the red subpixel (Red SP) and the green subpixel (Green SP).

The example embodiments described above will be briefly described as follows.

According to the example embodiments described herein, a display device can be provided that includes a substrate in which a normal area allowing a plurality of first pixels to be disposed and having a first resolution and an optical area allowing a plurality of second pixels to be disposed and having a second resolution less than the first resolution are defined, an electrode layer located over the substrate, a bank layer located over the substrate, covering a portion of the electrode layer, and including at least one open area, and a coating layer covering at least a portion of the bank layer in at least one of the normal area and the optical area.

In one or more aspects, the display device may further include an optical sensor overlapping with at least a portion of the coating layer and located under the bank layer.

In one or more aspects, the optical sensor may be an illuminance sensor.

In one or more aspects, the optical sensor may be located in the optical area.

In one or more aspects, in a coating material included in the coating layer, a rate absorbing light with wavelengths in the range of 495 nm to 570 nm may be higher than a rate absorbing light with wavelengths other than in the wavelength range of 495 nm to 570 nm.

In one or more aspects, the coating material may be one or more of copper, zirconium, iron, nickel, NaWO₃, ZnO, or TiO₂.

In one or more aspects, a plurality of subpixels including a red subpixel, a green subpixel, and a blue subpixel may be disposed over the substrate, and the coating layer may be located between the red subpixel and the green subpixel.

In one or more aspects, the display device may further include a hole transport layer located on the electrode layer and the bank layer, and covering the coating layer, and an emission layer located on the hole transport layer, and at least a portion of an emission layer of the red subpixel and at least a portion of an emission layer of the green subpixel overlap with each other on the coating layer

According to the example embodiments described herein, a display device can be provided that includes a substrate in which a normal area allowing a plurality of first pixels to be disposed and having a first resolution and an optical area allowing a plurality of second pixels to be disposed and having a second resolution less than the first resolution are defined, an electrode layer located over the substrate, a bank layer located over the substrate, covering a portion of the electrode layer, and including an open area, a dummy emission layer covering at least a portion of the bank layer in at least one of the normal area and the optical area, a hole transport layer located on the electrode layer and the bank layer and covering the dummy emission layer, and a main emission layer located on the hole transport layer.

In one or more aspects, light emitted from the dummy emission layer may have a wavelength less than light emitted from at least one of the main emission layer adjacent to the dummy emission layer.

In one or more aspects, the dummy emission layer may be a blue emission layer, and the at least one of the main emission layer adjacent to the dummy emission layer may be a red emission layer or a green emission layer.

In one or more aspects, the dummy emission layer may be a green emission layer, and the at least one of the main emission layer adjacent to the dummy emission layer may be a red emission layer.

In one or more aspects, the display device may further include an optical sensor overlapping with at least a portion of the dummy emission layer and located under the bank layer.

In one or more aspects, the optical sensor may be an illuminance sensor.

In one or more aspects, the optical sensor may be located in the optical area.

In one or more aspects, a plurality of subpixels including a red subpixel, a green subpixel, and a blue subpixel may be disposed over the substrate, and the dummy emission layer may be located between the red subpixel and the green subpixel.

In one or more aspects, at least a portion of an emission layer of the red subpixel and at least a portion of an emission layer of the green subpixel may overlap with each other on the dummy emission layer.

FIGS. 6A and 6B illustrate the second optical area OA2 as an example, but example embodiments of the present disclosure are not limited to this. The coating layer CL1 or the dummy emission layer CL2 described in FIGS. 6A and 6B may be equally, or substantially equally, applied to the first optical area OA1 or the normal area NA.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area in which a plurality of subpixels is disposed;
an electrode layer on the substrate;
a bank layer covering a portion of the electrode layer;
a coating layer covering at least a portion of the bank layer, the coating layer including a light absorbing material; and
an emission layer on the electrode layer, the bank layer, and the coating layer.

2. The display device of claim 1, wherein the display area includes a normal area having a first resolution and an optical area having a second resolution less than the first resolution, and
wherein the coating layer is located in at least one of the normal area and the optical area.

3. The display device of claim 2, further comprising an optical sensor located in the optical area.

4. The display device of claim 3, wherein the optical sensor overlaps with at least a portion of the coating layer and is located under the bank layer.

5. The display device of claim 3, wherein the optical sensor is an illuminance sensor.

6. The display device of claim 1, wherein, in the light absorbing material included in the coating layer, a rate absorbing light with wavelengths in a range of 495 nm to 570 nm is higher than a rate absorbing light with wavelengths other than in the wavelength range of 495 nm to 570 nm.

7. The display device of claim 1, wherein the light absorbing material includes one or more of copper, zirconium, iron, nickel, NaWO₃, ZnO, or TiO₂.

8. The display device of claim 1, wherein the coating layer is located between subpixels of different colors.

9. The display device of claim 8, further comprising:
a hole transport layer on the electrode layer and the bank layer, the hole transport layer covering the coating layer;
wherein the emission layer is on the hole transport layer,
wherein the emission layer of the subpixels of different colors overlaps with each other on the coating layer.

10. The display device of claim 8, wherein the plurality of subpixels includes a red subpixel, a green subpixel, and a blue subpixel, and
wherein the coating layer is located between the red subpixel and the green subpixel.

11. A display device, comprising:
a substrate including a display area in which a plurality of subpixels is disposed;
an electrode layer on the substrate;
a bank layer covering a portion of the electrode layer;
a dummy emission layer covering at least a portion of the bank layer, the dummy emission layer including a light emitting material;
a hole transport layer on the electrode layer and the bank layer and covering the dummy emission layer; and
a main emission layer on the hole transport layer.

12. The display device of claim 11, wherein the display area includes a normal area having a first pixel density and an optical area having a second pixel density less than the first pixel density, and
wherein the dummy emission layer is located in at least one of the normal area and the optical area.

13. The display device of claim 11, wherein light emitted from the dummy emission layer has a wavelength less than light emitted from at least one of the main emission layers adjacent to the dummy emission layer.

14. The display device of claim 13, wherein the dummy emission layer is a blue emission layer, and the at least one of the main emission layers adjacent to the dummy emission layer is either a red emission layer or a green emission layer.

15. The display device of claim 13, wherein the dummy emission layer is a green emission layer, and the at least one of the main emission layers adjacent to the dummy emission layer is a red emission layer.

16. The display device of claim 12, further comprising: an optical sensor located in the optical area,
wherein the optical sensor is an illuminance sensor.

17. The display device of claim 16, wherein the optical sensor overlaps with at least a portion of the dummy emission layer and located under the bank layer.

18. The display device of claim 11, wherein the dummy emission layer is located between subpixels of different colors.

19. The display device of claim 18, wherein the main emission layer of the subpixels of different colors overlaps with each other on the dummy emission layer.

20. The display device of claim 18, wherein the plurality of subpixels includes a red subpixel, a green subpixel, and a blue subpixel and
wherein the dummy emission layer is located between the red subpixel and the green subpixel.
